(19) United States
(12) Patent Application Publication
(10) Pub. No.: US 2022/0155650 A1
(43) Pub. Date: May 19, 2022

(54) WAVELENGTH CONVERSION SYSTEM, LASER SYSTEM, AND ELECTRONIC DEVICE MANUFACTURING METHOD

(71) Applicant: Gigaphoton Inc., Tochigi (JP)

(72) Inventors: Chen QU, Oyama-shi (JP); Hironori IGARASHI, Oyama-shi (JP); Atsushi FUCHIMUKAI, Oyama-shi (JP)

(73) Assignee: Gigaphoton Inc., Tochigi (JP)

(21) Appl. No.: 17/666,607

(22) Filed: Feb. 8, 2022

Related U.S. Application Data
(63) Continuation of application No. PCT/JP2019/036170, filed on Sep. 13, 2019.

(51) Int. Cl. G02F 1/35; G02F 1/355; H01S 3/00; G03F 7/20

(52) U.S. Cl. CPC G02F 1/3505; G02F 1/3551; G02F 1/3507; G03F 7/70025; G02F 1/3544; H01S 3/0092; G02F 1/3534

(57) ABSTRACT

A wavelength conversion system according to an aspect of the present disclosure includes a first crystal holder holding a first non-linear crystal, a second crystal holder holding a second non-linear crystal, a third crystal holder holding a third non-linear crystal, and a container housing the holders. The container has an entrance window and an emission window. The first non-linear crystal, the second non-linear crystal, and the third non-linear crystal are disposed in this order on an optical path of a laser beam traveling from the entrance window to the emission window. The crystal holders are rotatable. A first rotational axis that is a rotational axis of the first crystal holder is orthogonal to a second rotational axis that is a rotational axis of the second crystal holder, and the first rotational axis is parallel to a third rotational axis that is a rotational axis of the third crystal holder.

### CROSS-REFERENCE TO RELATED APPLICATIONS

The present application is a continuation application of International Application No. PCT/JP2019/036170, filed on Sep. 13, 2019, the entire contents of which are hereby incorporated by reference.

### BACKGROUND

### 1. Technical Field

The present disclosure relates to a wavelength conversion system, a laser system, and an electronic device manufacturing method.

### 2. Related Art

Recently, in a semiconductor exposure apparatus, resolving power improvement has been requested along with miniaturization and high integration of a semiconductor integrated circuit. Thus, the wavelength of light discharged from an exposure light source has been shortened. Examples of a gas laser apparatus for exposure include a KrF excimer laser apparatus configured to emit a laser beam having a wavelength of 248 nm approximately, and an ArF excimer laser apparatus configured to emit a laser beam having a wavelength of 193 nm approximately.

The KrF excimer laser apparatus and the ArF excimer laser apparatus each have a wide spectrum line width of 350 to 400 pm for spontaneous oscillation light. Thus, chromatic aberration occurs in some cases when a projection lens is made of a material that transmits ultraviolet light such as KrF and ArF laser beams. This can lead to resolving power decrease. Thus, the spectrum line width of a laser beam emitted from the gas laser apparatus needs to be narrowed so that chromatic aberration becomes negligible. Thus, to narrow the spectrum line width, a line narrowing module (LNM) including a line narrowing element (for example, etalon or grating) is provided in a laser resonator of the gas laser apparatus in some cases. In the following, a gas laser apparatus that achieves narrowing of the spectrum line width is referred to as a line narrowing gas laser apparatus.

### LIST OF DOCUMENTS

### Patent Documents

Patent Document 1: International Publication No. WO 2017/046860
Patent Document 2: Japanese Unexamined Patent Application Publication No. 2014-32277

### SUMMARY

A wavelength conversion system according to an aspect of the present disclosure includes a first crystal holder, a second crystal holder, a third crystal holder, and a container. The first crystal holder may hold a first non-linear crystal. The second crystal holder may hold a second non-linear crystal. The third crystal holder may hold a third non-linear crystal. The container may house the first crystal holder, the second crystal holder, and the third crystal holder. The container may have an entrance window and an emission window. The first non-linear crystal, the second non-linear crystal, and the third non-linear crystal may be disposed in this order on an optical path of a laser beam traveling from the entrance window to the emission window. The first crystal holder, the second crystal holder, and the third crystal holder each may be rotatable. A first rotational axis that is a rotational axis of the first crystal holder may be orthogonal to a second rotational axis that is a rotational axis of the second crystal holder. The first rotational axis may be parallel to a third rotational axis that is a rotational axis of the third crystal holder.

A laser system according to another aspect of the present disclosure includes a first solid-state laser apparatus, a second solid-state laser apparatus, and a wavelength conversion system. The first solid-state laser apparatus may be configured to emit a first pulse laser beam. The second solid-state laser apparatus may be configured to emit a second pulse laser beam. The wavelength conversion system may be configured to emit a third pulse laser beam having a wavelength different from wavelengths of the first pulse laser beam and the second pulse laser beam when having received the first pulse laser beam and the second pulse laser beam. The wavelength conversion system may include a first crystal holder, a second crystal holder, a third crystal holder, and a container. The first crystal holder may hold a first non-linear crystal. The second crystal holder may hold a second non-linear crystal. The third crystal holder may hold a third non-linear crystal. The container may house the first crystal holder, the second crystal holder, and the third crystal holder. The container may have an entrance window and an emission window. The first non-linear crystal, the second non-linear crystal, and the third non-linear crystal may be disposed in this order on an optical path of a laser beam traveling from the entrance window to the emission window. The first crystal holder, the second crystal holder, and the third crystal holder each may be rotatable. A first rotational axis that is a rotational axis of the first crystal holder may be orthogonal to a second rotational axis that is a rotational axis of the second crystal holder. The first rotational axis may be parallel to a third rotational axis that is a rotational axis of the third crystal holder.

An electronic device manufacturing method according to another aspect of the present disclosure includes generating a laser beam with a laser system including a wavelength conversion system, emitting the laser beam to an exposure apparatus, and exposing a photosensitive substrate to the laser beam within the exposure apparatus to manufacture an electronic device. The wavelength conversion system may include a first crystal holder, a second crystal holder, a third crystal holder, and a container. The first crystal holder may hold a first non-linear crystal. The second crystal holder may hold a second non-linear crystal. The third crystal holder may hold a third non-linear crystal. The container may house the first crystal holder, the second crystal holder, and the third crystal holder. The container may have an entrance window and an emission window. The first non-linear crystal, the second non-linear crystal, and the third non-linear crystal may be disposed in this order on an optical path of a laser beam traveling from the entrance window to the emission window. The first crystal holder, the second crystal holder, and the third crystal holder each may be rotatable. A first rotational axis that is a rotational axis of the first crystal holder may be orthogonal to a second rotational axis that is a rotational axis of the second crystal holder. The first rotational axis may be parallel to a third rotational axis that is a rotational axis of the third crystal holder.

### BRIEF DESCRIPTION OF THE DRAWINGS

Embodiments of the present disclosure will be described below as examples with reference to the accompanying drawings.

FIG. 1 schematically illustrates an exemplary configuration of a laser apparatus according to a comparative example.

FIG. 2 schematically illustrates an exemplary configuration of an amplifier illustrated in FIG. 1.

FIG. 3 schematically illustrates an exemplary configuration of a solid-state laser system including a wavelength conversion system according to Embodiment 1.

FIG. 4 schematically illustrates an exemplary configuration of the wavelength conversion system according to Embodiment 1.

FIG. 5 is a cross-sectional view illustrating an exemplary configuration of a holder.

FIG. 6 is a bottom view of the holder illustrated in FIG. 5.

FIG. 7 schematically illustrates an exemplary configuration of a wavelength conversion system according to Embodiment 2.

FIG. 8 schematically illustrates an exemplary configuration of a solid-state laser system including a wavelength conversion system according to Embodiment 3.

FIG. 9 is a diagram schematically illustrating an exemplary configuration of an exposure apparatus.

### DESCRIPTION OF EMBODIMENTS

### Contents

1. Overview of laser apparatus according to comparative example

### 1.1 Configuration

1.1.1 Overall configuration
1.1.2 Configuration of amplifier

### 1.2 Operation

### 1.3 Problems

### 2. Embodiment 1

### 2.1 Configuration

2.1.1 Configuration of solid-state laser system
2.1.2 Configuration of wavelength conversion system

### 2.2 Operation

2.2.1 Operation of solid-state laser system
2.2.2 Operation of wavelength conversion system
2.3 Specific example of crystal holder

### 2.3.1 Configuration

### 2.3.2 Operation

### 2.4 Effects

### 3. Embodiment 2

### 3.1 Configuration

### 3.2 Operation

### 3.3 Effects

### 4. Embodiment 3

### 4.1 Configuration

### 4.2 Operation

### 4.3 Effects

### 4.4 Modification

5. Example of wavelength adjustable range

### 6. Modifications

7. Electronic device manufacturing method

### 8. Others

Embodiments of the present disclosure will be described below in detail with reference to the accompanying drawings. The embodiments described below are examples of the present disclosure, and do not limit the contents of the present disclosure. Not all configurations and operations described in each embodiment are necessarily essential as configurations and operations of the present disclosure. Components identical to each other are denoted by the same reference sign, and duplicate description thereof will be omitted.

### 1. Overview of Laser Apparatus According to Comparative Example

1.1 Configuration

1.1.1 Overall Configuration

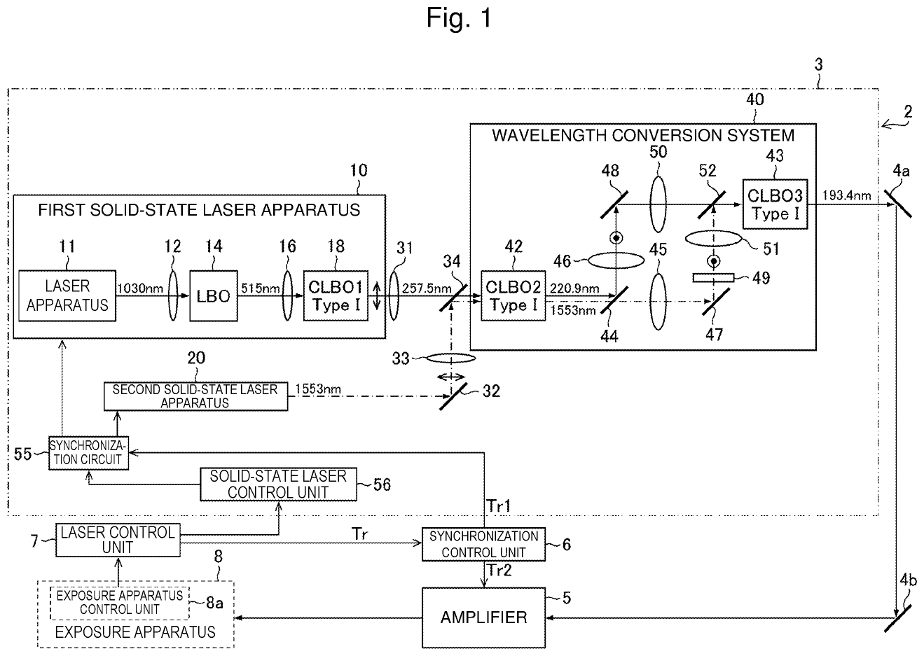

FIG. 1 schematically illustrates an exemplary configuration of a laser apparatus 2 according to a comparative example. The laser apparatus 2 is an excimer laser apparatus for an exposure apparatus including a solid-state laser system 3, high reflective mirrors 4a and 4b, an amplifier 5, a synchronization control unit 6, and a laser control unit 7. The solid-state laser system 3 includes a first solid-state laser apparatus 10, a second solid-state laser apparatus 20, a light condensing lens 31, a high reflective mirror 32, a light condensing lens 33, a first dichroic mirror 34, a wavelength conversion system 40, a synchronization circuit 55, and a solid-state laser control unit 56.

The first solid-state laser apparatus 10 includes a laser apparatus 11 configured to emit a pulse laser beam having a wavelength of 1030 nm approximately, a light condensing lens 12, an LBO crystal 14, a light condensing lens 16, and a CLBO crystal 18. The material LBO is expressed by the chemical formula LiB₃O₅. The material CLBO is expressed by the chemical formula CsLiB₆D₁₀. The LBO crystal 14 and the CLBO crystal 18 are non-linear crystals for wavelength conversion. The term “non-linear crystal” is synonymous with “non-linear optical crystal”. A non-linear crystal for wavelength conversion is referred to as a “wavelength conversion crystal”.

Although no detailed configuration of the laser apparatus 11 is illustrated, the laser apparatus 11 includes, for example, a first seed laser, a first optical switch, and a first amplifier. The first seed laser is of a single longitudinal mode and emits continuous wave (CW) light or pulse light having a wavelength of 1030 nm approximately as first seed light. The first seed laser is, for example, a distribution feedback (DFB) semiconductor laser and has an oscillation wavelength that can be changed by changing setting of the temperature of a semiconductor. The term “approximately” used together with a numerical value indicating a wavelength indicates that the wavelength may include a numerical value in an allowed wavelength range near the numerical value of the wavelength.

The first optical switch is, for example, a semiconductor optical amplifier (SOA). The first seed light from the first seed laser is incident on the first optical switch and converted into a laser beam having a predetermined pulse width. The pulse light emitted from the first optical switch is referred to as first seed pulse light.

The first amplifier includes, for example, a fiber amplifier, a solid-state amplifier, and an excitation semiconductor laser. The fiber amplifier may be configured as a plurality of quartz fibers doped with Yb (ytterbium) and connected in a multi-stage configuration. The solid-state amplifier may be, for example, an amplifier including an yttrium aluminum garnet (YAG) crystal doped with Yb. The fiber amplifier and the solid-state amplifier are photoexcited by CW excitation light received from the excitation semiconductor laser. The first amplifier amplifies the first seed pulse light incident from the first optical switch.

The light condensing lens 12 is disposed on an optical path between the laser apparatus 11 and the LBO crystal 14. The light condensing lens 16 is disposed on an optical path between the LBO crystal 14 and the CLBO crystal 18. In FIG. 1, the CLBO crystal 18 is referred to as “CLBO1”.

The LBO crystal 14 is a wavelength conversion element configured to convert a pulse laser beam having a wavelength of 1030 nm approximately into a pulse laser beam having a wavelength of 515 nm approximately. The CLBO crystal 18 is a wavelength conversion element configured to convert a pulse laser beam having a wavelength of 515 nm approximately into a pulse laser beam having a wavelength of 257.5 nm approximately. The CLBO crystal 18 is a wavelength conversion crystal having a phase matching condition of type 1.

Fourth harmonic light having a wavelength of 257.5 nm approximately is generated from the first seed pulse light having a wavelength of 1030 nm approximately through the combination of two wavelength conversion crystals, the LBO crystal 14 and the CLBO crystal 18. The first solid-state laser apparatus 10 emits the pulse laser beam having a wavelength of 257.5 nm approximately.

The light condensing lens 31 is disposed on an optical path between the CLBO crystal 18 and the first dichroic mirror 34.

The second solid-state laser apparatus 20 emits a pulse laser beam having a wavelength of 1553 nm approximately. Although no detailed configuration of the second solid-state laser apparatus 20 is illustrated, the second solid-state laser apparatus 20 includes, for example, a second seed laser, a second optical switch, and a second amplifier. The second seed laser is of a single longitudinal mode and emits CW light or pulse light having a wavelength of 1553 nm approximately as second seed light. The second seed laser is, for example, a distribution feedback (DFB) semiconductor laser and has an oscillation wavelength that can be changed by changing setting of the temperature of a semiconductor. The second optical switch is, for example, a semiconductor optical amplifier (SOA). The second seed light from the second seed laser is incident on the second optical switch and converted into a laser beam having a predetermined pulse width. The second seed light emitted from the second optical switch is referred to as second seed pulse light.

The second amplifier includes, for example, an Er (erbium) fiber amplifier configured as a plurality of quartz fibers doped with Er and Yb and connected in a multi-stage configuration, and an excitation semiconductor laser. The Er fiber amplifier is photoexcited by CW excitation light received from the excitation semiconductor laser. The second amplifier amplifies the second seed pulse light incident from the second optical switch. The second solid-state laser apparatus 20 emits the pulse laser beam amplified by the second amplifier.

The high reflective mirror 32 and the first dichroic mirror 34 are disposed so that the pulse laser beam emitted from the second solid-state laser apparatus 20 is received by a CLBO crystal 42 of the wavelength conversion system 40. The light condensing lens 33 is disposed on an optical path between the high reflective mirror 32 and the first dichroic mirror 34.

The first dichroic mirror 34 is coated with a film that highly transmits the pulse laser beam having a wavelength of 257.5 nm approximately and emitted from the first solid-state laser apparatus 10 and highly reflects the pulse laser beam having a wavelength of 1553 nm approximately and emitted from the second solid-state laser apparatus 20. The first dichroic mirror 34 is disposed so that the pulse laser beams emitted from the first solid-state laser apparatus 10 and the second solid-state laser apparatus 20, respectively, are incident on the wavelength conversion system 40 in a state in which the optical path axes of the pulse laser beams are substantially aligned with each other.

When having received the pulse laser beam having a wavelength of 257.5 nm approximately and the pulse laser beam having a wavelength of 1553 nm approximately, the wavelength conversion system 40 emits a pulse laser beam having a wavelength of 193.4 nm approximately.

The wavelength conversion system 40 includes the CLBO crystal 42 as a wavelength conversion element, and a CLBO crystal 43. The wavelength conversion system 40 includes, in addition to the two CLBO crystals 42 and 43, a second dichroic mirror 44, a collimator lens 45, a collimator lens 46, a high reflective mirror 47, a high reflective mirror 48, a half-wavelength plate 49, a light condensing lens 50, a light condensing lens 51, and a third dichroic mirror 52.

The CLBO crystal 42 and the CLBO crystal 43 of the wavelength conversion system 40 each are a non-linear crystal having a phase matching condition of type 1. In FIG. 1, the CLBO crystal 42 is referred to as “CLBO2”, and the CLBO crystal 43 is referred to as “CLBO3”.

The CLBO crystal 42 receives the pulse laser beam having a wavelength of 257.5 nm approximately and emitted from the first solid-state laser apparatus 10 and the pulse laser beam having a wavelength of 1553 nm approximately and emitted from the second solid-state laser apparatus 20. The CLBO crystal 42 emits a pulse laser beam having a wavelength of 220.9 nm approximately, which is sum frequency light of the pulse laser beam having a wavelength of 257.5 nm approximately and the pulse laser beam having a wavelength of 1553 nm approximately, the pulse laser beam having a wavelength of 257.5 nm approximately, and the pulse laser beam having a wavelength of 1553 nm approximately.

The second dichroic mirror 44, the collimator lens 45, the high reflective mirror 47, the half-wavelength plate 49, the light condensing lens 51, and the third dichroic mirror 52 are disposed in this order on the optical path of the pulse laser beam having a wavelength of 1553 nm approximately and emitted from the CLBO crystal 42. The second dichroic mirror 44, the collimator lens 46, the high reflective mirror 48, the light condensing lens 50, and the third dichroic mirror 52 are disposed in this order on the optical path of the pulse laser beam having a wavelength of 220.9 nm approximately and emitted from the CLBO crystal 42.

The second dichroic mirror 44 is coated with a film that highly transmits a pulse laser beam having a wavelength of 257.5 nm approximately and a pulse laser beam having a wavelength of 1553 nm approximately and highly reflects a pulse laser beam having a wavelength of 220.9 nm approximately. The half-wavelength plate 49 rotates the polarization direction of a transmitted pulse laser beam by 90°.

The third dichroic mirror 52 is coated with a film that highly transmits a pulse laser beam having a wavelength of 220.9 nm approximately and highly reflects a pulse laser beam having a wavelength of 1553 nm approximately.

The CLBO crystal 43 receives the pulse laser beam having a wavelength of 220.9 nm approximately and emitted from the CLBO crystal 42 and the pulse laser beam having a wavelength of 1553 nm approximately. The CLBO crystal 43 emits a pulse laser beam having a wavelength of 193.4 nm approximately, which is sum frequency light of the pulse laser beam having a wavelength of 220.9 nm approximately and the pulse laser beam having a wavelength of 1553 nm approximately.

The high reflective mirrors 4a, 4b, 32, 47, and 48 each are coated with a high reflective film corresponding to a wavelength to be reflected.

The high reflective mirrors 4a and 4b are disposed so that the pulse laser beam having a wavelength of 193.4 nm approximately and emitted from the wavelength conversion system 40 is incident on the amplifier 5. One or both of the high reflective mirrors 4a and 4b may be omitted depending on the disposition relation between the wavelength conversion system 40 and the amplifier 5.

The solid-state laser control unit 56 is electrically connected to the synchronization circuit 55 through a non-illustrated signal line. The synchronization circuit 55 may be included in the solid-state laser control unit 56. The synchronization circuit 55 is electrically connected to the first optical switch in the first solid-state laser apparatus 10 and the second optical switch in the second solid-state laser apparatus 20 through non-illustrated signal lines.

The solid-state laser control unit 56 is electrically connected to the first seed laser and the excitation semiconductor laser in the first solid-state laser apparatus 10 and the second seed laser and the excitation semiconductor laser in the second solid-state laser apparatus 20 through non-illustrated signal lines.

The laser control unit 7 is connected to the solid-state laser control unit 56 and an exposure apparatus control unit 8a to perform communication therebetween. The exposure apparatus control unit 8a is a controller configured to control an exposure apparatus 8.

Controllers that function as the laser control unit 7, the solid-state laser control unit 56, the synchronization control unit 6, the exposure apparatus control unit 8a, and any other control unit may be configured as a combination of hardware and software of one or a plurality of computers. The term “software” is synonymous with a computer program. A computer includes a central processing unit (CPU) and a memory. A CPU included in a computer is an example of a processor. A programmable controller and a sequencer are included in the concept of computers.

Some or all of processing functions of a controller may be achieved by using an integrated circuit such as a field programmable gate array (FPGA) or an application specific integrated circuit (ASIC). Functions of a plurality of controllers may be achieved with one controller. In the present disclosure, controllers may be connected to each other through a communication network such as a local area network or the Internet. In a distributed computing environment, a program unit may be stored in both local and remote memory storage devices.

1.1.2 Configuration of Amplifier

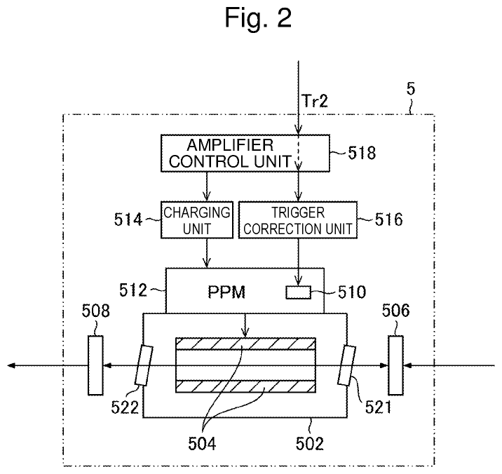

FIG. 2 schematically illustrates an exemplary configuration of the amplifier 5 illustrated in FIG. 1. The amplifier 5 is an excimer laser amplifier. The amplifier 5 includes a chamber 502, a pair of discharge electrodes 504, a partial reflective mirror 506, an output coupling mirror 508, a pulse power module (PPM) 512 including a switch 510, a charging unit 514, a trigger correction unit 516, and an amplifier control unit 518.

The chamber 502 has windows 521 and 522. The chamber 502 encapsulates laser gas including, for example, Ar gas, F₂ gas, and Ne gas. The discharge electrodes 504 are disposed in the chamber 502. The discharge electrodes 504 are connected to an output terminal of the PPM 512.

An optical resonator including the partial reflective mirror 506 and the output coupling mirror 508 is constituted in the amplifier 5. The partial reflective mirror 506 is formed by, for example, coating a substrate made of a CaF₂ crystal that transmits light having a wavelength of 193.4 nm approximately with a partial reflective film having a reflectance of 70% to 90%. The output coupling mirror 508 is formed by, for example, coating a substrate made of a CaF₂ crystal that transmits light having a wavelength of 193.4 nm approximately with a partial reflective film having a reflectance of 10% to 20%.

Although FIG. 2 illustrates an example in which the amplifier 5 includes the optical resonator that is a Fabry-Perot resonator, the present invention is not limited to this example and the optical resonator may be a ring resonator or an expanding 3-pass amplifier. In the enlarging 3-pass amplifier, a convex mirror and a concave mirror are disposed outside a chamber, and beam enlargement and amplification are performed as the pulse laser beam having a wavelength of 193.4 nm approximately and emitted from the solid-state laser system 3 is reflected by the convex mirror and the concave mirror and passes through a discharge space in the chamber three times.

1.2 Operation

The operation of the laser apparatus 2 according to the comparative example will be described below. The laser control unit 7 operates each of the first seed laser in the first solid-state laser apparatus 10 and the second seed laser in the second solid-state laser apparatus 20 through the solid-state laser control unit 56 to perform CW oscillation at the excitation semiconductor laser. The synchronization control unit 6 receives, from the solid-state laser control unit 56, delay data of a first trigger signal Tr1 and a second trigger signal Tr2.

When having received an oscillation trigger signal Tr from the exposure apparatus control unit 8a through the laser control unit 7, the synchronization control unit 6 controls a delay time between the first trigger signal Tr1 and the second trigger signal Tr2. Specifically, the synchronization control unit 6 controls the delay time between the first trigger signal Tr1 and the second trigger signal Tr2 so that discharge occurs in synchronization with a timing at which a pulse laser beam emitted from the solid-state laser system 3 is injected into the chamber 502 of the amplifier 5.

When having received the first trigger signal Tr1, the synchronization circuit 55 transmits a control signal for converting seed light into pulse light of a predetermined pulse waveform to each of the first optical switch in the laser apparatus 11 of the first solid-state laser apparatus 10 and the second optical switch in the second solid-state laser apparatus 20. When having received the control signal, the first optical switch generates a first seed pulse light having a predetermined pulse width and a light intensity by amplifying the first seed light only in a duration specified by the control signal. The first seed pulse light is incident on the first amplifier, amplified by the first amplifier, and then emitted from the laser apparatus 11.

Similarly, when having received the control signal, the second optical switch in the second solid-state laser apparatus 20 generates a second seed pulse light having a pulse width and a light intensity specified by the control signal. The second seed pulse light is incident on the second amplifier, amplified by the second amplifier, and then emitted from the second solid-state laser apparatus 20.

The seed pulse light having a wavelength of 1030 nm approximately and emitted from the laser apparatus 11 of the first solid-state laser apparatus 10 is incident on the LBO crystal 14 through the light condensing lens 12 and converted into a pulse laser beam having a wavelength of 515 nm approximately by the LBO crystal 14.

The pulse laser beam having a wavelength of 515 nm approximately and emitted from the LBO crystal 14 is incident on the CLBO crystal 18 through the light condensing lens 16. The incident angle on the CLBO crystal 18 is adjusted so that the pulse laser beam having a wavelength of 515 nm approximately satisfies a phase matching condition. As a result, a pulse laser beam having a wavelength of 257.5 nm approximately corresponding to the second harmonic of the pulse laser beam having a wavelength of 515 nm approximately is generated. In FIG. 1, a double-headed arrow illustrated on the optical path of the pulse laser beam having a wavelength of 257.5 nm approximately indicates the polarization direction of the pulse laser beam.

The pulse laser beam having a wavelength of 257.5 nm approximately and emitted from the first solid-state laser apparatus 10 is incident on the first dichroic mirror 34 through the light condensing lens 31.

A pulse laser beam having a wavelength of 1553 nm approximately and emitted from the second solid-state laser apparatus 20 is incident on the first dichroic mirror 34 through the high reflective mirror 32 and the light condensing lens 33. In FIG. 1, a double-headed arrow illustrated on the optical path of the pulse laser beam having a wavelength of 1553 nm approximately indicates the polarization direction of the pulse laser beam.

The pulse laser beam having a wavelength of 257.5 nm approximately and emitted from the first solid-state laser apparatus 10 and the pulse laser beam having a wavelength of 1553 nm approximately and emitted from the second solid-state laser apparatus 20 are substantially simultaneously incident on the CLBO crystal 42 with substantially identical optical path axes. The pulse laser beam having a wavelength of 257.5 nm approximately and the pulse laser beam having a wavelength of 1553 nm approximately, both incident on the CLBO crystal 42 are linearly polarized and have polarization directions parallel to each other in the comparative example. The term “parallel” in the present specification may include the concept of being substantially parallel, which can be regarded as being parallel in effect in technological meanings.

The CLBO crystal 42 performs wavelength conversion by phase matching of type 1 and has a phase matching condition for pulse laser beams having polarization directions parallel to each other. Thus, the incident angle on the CLBO crystal 42 is adjusted so that the phase matching condition is satisfied by the pulse laser beam having a wavelength of 257.5 nm approximately and the pulse laser beam having a wavelength of 1553 nm approximately. As a result, a pulse laser beam having a wavelength of 220.9 nm approximately, which is the sum frequency of the pulse laser beam having a wavelength of 257.5 nm approximately and the pulse laser beam having a wavelength of 1553 nm approximately, is generated through sum frequency mixing at the CLBO crystal 42. The CLBO crystal 42 emits the pulse laser beam having a wavelength of 220.9 nm approximately, the pulse laser beam having a wavelength of 257.5 nm approximately, and the pulse laser beam having a wavelength of 1553 nm approximately.

The second dichroic mirror 44 reflects the pulse laser beam having a wavelength of 220.9 nm approximately and transmits the pulse laser beam having a wavelength of 1553 nm approximately and the pulse laser beam having a wavelength of 257.5 nm approximately.

The pulse laser beam having a wavelength of 220.9 nm approximately and reflected by the second dichroic mirror 44 is incident on the third dichroic mirror 52 through the collimator lens 46, the high reflective mirror 48, and the light condensing lens 50. A circled black dot symbol illustrated on the optical path of the pulse laser beam having a wavelength of 220.9 nm approximately indicates that the pulse laser beam has a polarization direction perpendicular to the sheet of the diagram.

The pulse laser beam having a wavelength of 1553 nm approximately and having transmitted through the second dichroic mirror 44 is incident on the half-wavelength plate 49 through the collimator lens 45 and the high reflective mirror 47. The polarization direction of the pulse laser beam having a wavelength of 1553 nm approximately is rotated by 90° as the pulse laser beam transmits through the half-wavelength plate 49. As a result, the polarization directions of the pulse laser beam having a wavelength of 220.9 nm approximately and the pulse laser beam having a wavelength of 1553 nm approximately, both incident on the CLBO crystal 43 become parallel to each other. A circled black dot symbol illustrated on the optical path of the pulse laser beam having a wavelength of 1553 nm approximately indicates that the pulse laser beam has a polarization direction perpendicular to the sheet of the diagram.

The pulse laser beam having transmitted through the half-wavelength plate 49 is incident on the third dichroic mirror 52 through the light condensing lens 51. The third dichroic mirror 52 reflects the pulse laser beam having a wavelength of 1553 nm approximately and transmits the pulse laser beam having a wavelength of 220.9 nm approximately and the pulse laser beam having a wavelength of 257.5 nm approximately. The optical path axis of the pulse laser beam having a wavelength of 220.9 nm approximately and the optical path axis of the pulse laser beam having a wavelength of 1553 nm approximately and a polarization direction rotated by 90° through the half-wavelength plate 49 are substantially aligned with each other at the third dichroic mirror 52, and then both pulse laser beams are incident on the CLBO crystal 43.

The polarization directions of the pulse laser beam having a wavelength of 220.9 nm approximately and the pulse laser beam having a wavelength of 1553 nm approximately, both incident on the CLBO crystal 43 are parallel to each other. The CLBO crystal 43 performs wavelength conversion by phase matching of type 1 and has a phase matching condition for pulse laser beams having polarization directions parallel to each other. Thus, the incident angle on the CLBO crystal 43 is adjusted so that the phase matching condition is satisfied by the pulse laser beam having a wavelength of 220.9 nm approximately and the pulse laser beam having a wavelength of 1553 nm approximately. As a result, a pulse laser beam having a wavelength of 193.4 nm approximately, which is the sum frequency of the pulse laser beam having a wavelength of 220.9 nm approximately and the pulse laser beam having a wavelength of 1553 nm approximately is generated through sum frequency mixing at the CLBO crystal 43.

Accordingly, the pulse laser beam having a wavelength of 193.4 nm approximately is emitted from the wavelength conversion system 40. The pulse laser beam having a wavelength of 193.4 nm approximately, which is generated by the wavelength conversion system 40, is highly reflected by the high reflective mirrors 4a and 4b and received by the amplifier 5.

At the amplifier 5, discharge is performed in synchronization with the reception of the pulse laser beam having a wavelength of 193.4 nm approximately, and inverted distribution is generated. The trigger correction unit 516 adjusts the timing of the switch 510 of the PPM 512 so that the pulse laser beam received by the amplifier 5 is efficiently amplified by the amplifier 5. As a result, the amplified pulse laser beam subjected to amplified oscillation at the optical resonator is emitted from the output coupling mirror 508. The pulse laser beam having a wavelength of 193.4 nm approximately and emitted from the amplifier 5 is received by the exposure apparatus 8.

1.3 Problems

The configuration of the comparative example illustrated in FIG. 1 has problems as follows.

[Problem 1] A plurality of optical elements for bifurcating a pulse laser beam or merging pulse laser beams exist between the CLBO crystal 18 and the CLBO crystal 42 and between the CLBO crystal 42 and the CLBO crystal 43, and thus the installation area of a wavelength conversion unit including the wavelength conversion system 40 is large. Specifically, the light condensing lens 31 and the first dichroic mirror 34 are disposed between the CLBO crystal 18 and the CLBO crystal 42. In addition, the second dichroic mirror 44, the third dichroic mirror 52, the collimator lenses 45 and 46, the high reflective mirrors 47 and 48, the half-wavelength plate 49, and the light condensing lenses 50 and 51 are disposed between the CLBO crystal 42 and the CLBO crystal 43. With this configuration, the installation area of the wavelength conversion unit including these optical elements is large.

[Problem 2] A CLBO crystal is deliquescent, and thus when the CLBO crystal is infiltrated with water, its surface on which a pulse laser beam is incident is clouded and transmittance significantly degrades. To avoid this, the CLBO crystal needs dehydration processing and purge for preventing water adhesion. In the configuration of the comparative example illustrated in FIG. 1, the volume of spaces in which the CLBO crystals 18, 42, and 43 are disposed is large, and thus it is difficult to efficiently perform dehydration processing and purge for preventing water adhesion on the CLBO crystals.

[Problem 3] The optical path length between the CLBO crystal 18 and the CLBO crystal 42 and the optical path length between the CLBO crystal 42 and the CLBO crystal 43 are long, and thus it takes time to adjust alignment.

[Problem 4] Dichroic mirrors and collimator lenses have small damage thresholds for ultraviolet light, which makes it difficult to have high-power emission.

### 2. Embodiment 1

2.1 Configuration

2.1.1 Configuration of Solid-State Laser System

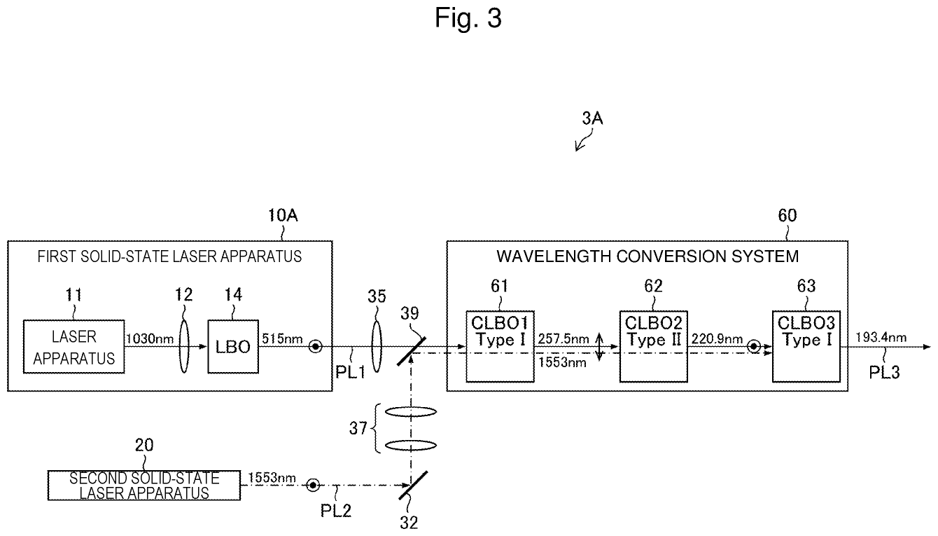

FIG. 3 schematically illustrates an exemplary configuration of a solid-state laser system 3A according to Embodiment 1. In Embodiment 1, the solid-state laser system 3A illustrated in FIG. 3 is applied in place of the solid-state laser system 3 described with reference to FIG. 1. In FIG. 3, a part same as a component of the laser apparatus 2 according to the comparative example illustrated in FIG. 1 is denoted by the same reference sign, and description thereof is omitted as appropriate. Illustrations of the synchronization circuit 55 and the solid-state laser control unit 56 are omitted in FIG. 3.

The solid-state laser system 3A includes a first solid-state laser apparatus 10A, the second solid-state laser apparatus 20, a collimator lens 35, the high reflective mirror 32, a beam expander lens 37, a dichroic mirror 39, and a wavelength conversion system 60.

The first solid-state laser apparatus 10A includes the laser apparatus 11, the light condensing lens 12, and the LBO crystal 14. The first solid-state laser apparatus 10A emits a pulse laser beam PL1 generated by the LBO crystal 14 and having a wavelength of 515 nm approximately. The second solid-state laser apparatus 20 emits a pulse laser beam PL2 having a wavelength of 1553 nm approximately. The pulse laser beam PL1 is an example of a “first pulse laser beam” in the present disclosure. The pulse laser beam PL2 is an example of a “second pulse laser beam” in the present disclosure.

The wavelength conversion system 60 includes a first CLBO crystal 61, a second CLBO crystal 62, and a third CLBO crystal 63. The first CLBO crystal 61 and the third CLBO crystal 63 each are a wavelength conversion crystal having a phase matching condition of type 1. The second CLBO crystal 62 is a wavelength conversion crystal having a phase matching condition of type 2. In FIG. 3, the first CLBO crystal 61 is referred to as “CLBO1”, the second CLBO crystal 62 is referred to as “CLBO2”, and the third CLBO crystal 63 is referred to as “CLBO3”.

The collimator lens 35 and the dichroic mirror 39 are disposed on the optical path of the pulse laser beam PL1 between the first solid-state laser apparatus 10A and the wavelength conversion system 60. The high reflective mirror 32 and the dichroic mirror 39 are disposed so that the pulse laser beam PL2 emitted from the second solid-state laser apparatus 20 is received by the first CLBO crystal 61 of the wavelength conversion system 60. The beam expander lens 37 is disposed on an optical path between the high reflective mirror 32 and the dichroic mirror 39. The beam expander lens 37 may be configured as a pair of a concave lens and a convex lens.

The dichroic mirror 39 is coated with a film that highly transmits a pulse laser beam having a wavelength of 515 nm approximately and emitted from the first solid-state laser apparatus 10A and highly reflects a pulse laser beam having a wavelength of 1553 nm approximately and emitted from the second solid-state laser apparatus 20. The dichroic mirror 39 is disposed so that the pulse laser beam PL1 emitted from the first solid-state laser apparatus 10A and the pulse laser beam PL2 emitted from the second solid-state laser apparatus 20 are incident on the wavelength conversion system 60 in a state in which the optical path axes thereof are substantially aligned with each other.

When having received the pulse laser beam PL1 having a wavelength of 515 nm approximately and emitted from the first solid-state laser apparatus 10A and the pulse laser beam PL2 having a wavelength of 1553 nm approximately and emitted from the second solid-state laser apparatus 20, the wavelength conversion system 60 generates a pulse laser beam PL3 having a wavelength of 193.4 nm approximately, which is a wavelength different from those of the pulse laser beam PL1 and the pulse laser beam PL2.

2.1.2 Configuration of Wavelength Conversion System

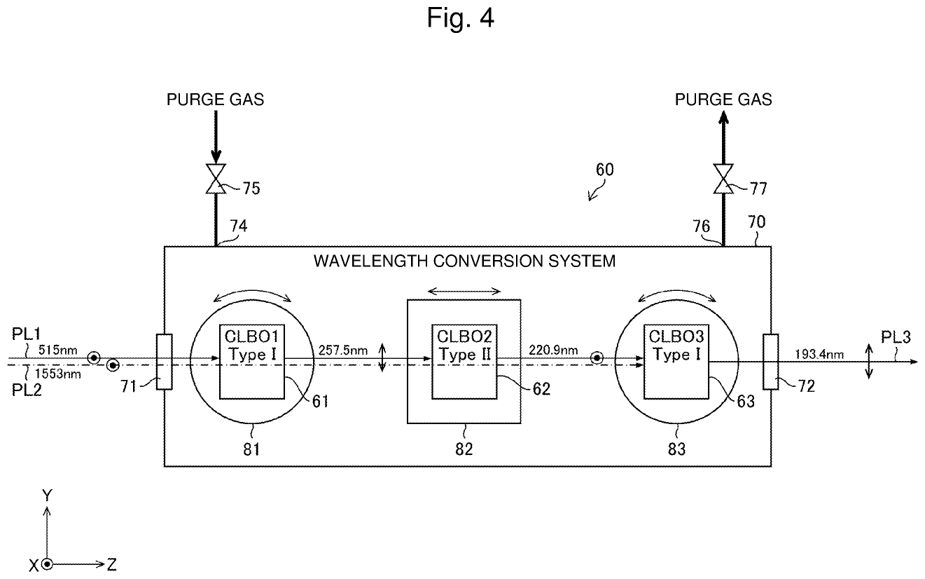

FIG. 4 schematically illustrates an exemplary configuration of the wavelength conversion system 60 according to Embodiment 1. The wavelength conversion system 60 includes a sealable container 70 that is a housing, a first window 71, a second window 72, a first holder 81 holding the first CLBO crystal 61, a second holder 82 holding the second CLBO crystal 62, and a third holder 83 holding the third CLBO crystal 63.

The directions of an X axis, a Y axis, and a Z axis as three axes orthogonal to one another are defined as illustrated in FIG. 4. The Z axial direction is the directions of the optical path axes of the pulse laser beams PL1 and PL2 incident on the wavelength conversion system 60. The X axial direction is orthogonal to the Z axial direction and perpendicular to the sheet of the diagram in FIG. 4. The Y axial direction is orthogonal to the Z axial direction and the X axial direction and is the longitudinal direction in FIG. 4. In FIG. 4, the direction perpendicular to the sheet of the diagram is an example of a “first direction” in the present disclosure. The longitudinal direction illustrated as the Y axial direction in FIG. 4 is an example of a “second direction” in the present disclosure.

The first CLBO crystal 61 is fixed to the first holder 81. The first holder 81 includes a rotation mechanism that is rotatable about a rotational axis parallel to the X axial direction. The second CLBO crystal 62 is fixed to the second holder 82. The second holder 82 includes a rotation mechanism that is rotatable about a rotational axis parallel to the Y axial direction. The third CLBO crystal 63 is fixed to the third holder 83. The third holder 83 includes a rotation mechanism that is rotatable about a rotational axis parallel to the X axial direction. The first holder 81, the second holder 82, and the third holder 83 are housed in the container 70.

The container 70 is provided with holes for attaching the first window 71 and the second window 72, and the first window 71 and the second window 72 are fixed to the respective holes. The first window 71 is an entrance window through which the pulse laser beams PL1 and PL2 are incident in the container 70. The second window 72 is an emission window through which the pulse laser beam PL3 generated by the third CLBO crystal 63 and having a wavelength of 193.4 nm approximately is emitted out of the container 70.

The first window 71 and the second window 72 are made of a material having a high transmittance in a range from infrared region to a deep ultraviolet region with a wavelength equal to or shorter than 200 nm approximately. The material of the first window 71 and the second window 72 may be, for example, CaF₂.

The container 70 may have, for example, a rectangular tube shape long in the Z axial direction. The first window 71 is disposed at an end part on the incident side in the Z axial direction in the container 70. The second window 72 is disposed at an end part on the emission side in the Z axial direction in the container 70.

The first CLBO crystal 61, the second CLBO crystal 62, and the third CLBO crystal 63 are disposed in this order on the optical path of a laser beam traveling from the first window 71 to the second window 72.

The first holder 81 and the third holder 83 are attached to, for example, holes provided to a wall surface orthogonal to the X axial direction in the container 70 (a wall surface parallel to the YZ plane). The second holder 82 is attached to, for example, a hole provided to a wall surface orthogonal to the Y axial direction in the container 70 (a wall surface parallel to the XZ plane).

The container 70 is provided with a gas introduction port 74 and a gas discharge port 76 to purge the inside of the container 70 with inert gas. The inert gas may be, for example, Ar gas. As the purge gas, N₂ gas may be used in place of or in combination with Ar gas.

A non-illustrated gas supply source is connected to the gas introduction port 74. A valve 75 is disposed on a gas flow path connected to the gas introduction port 74. Similarly, a valve 77 is disposed on a gas flow path connected to the gas discharge port 76. The valves 75 and 77 are controlled by the solid-state laser control unit 56.

The distance between the gas introduction port 74 and the gas discharge port 76 is preferably as long as possible to efficiently purge the inside of the container 70. FIG. 4 illustrates an example in which the gas introduction port 74 is disposed near the first CLBO crystal 61 on the laser-beam incident side in the container 70 and the gas discharge port 76 is disposed on the third CLBO crystal 63 side, but the gas introduction port 74 may be disposed on the third CLBO crystal 63 side and the gas discharge port 76 may be disposed on the first CLBO crystal 61 side.

2.2 Operation

2.2.1 Operation of Solid-State Laser System

The operation of the solid-state laser system 3A illustrated in FIG. 3 will be described below. The first solid-state laser apparatus 10A emits the pulse laser beam PL1 having a wavelength of 515 nm approximately. The polarization direction of the pulse laser beam PL1 is perpendicular to the sheet of FIG. 3. The polarization direction of the pulse laser beam PL1 is an example of a “first polarization direction” in the present disclosure. The pulse laser beam PL1 is incident on the dichroic mirror 39 through the collimator lens 35. The collimator lens 35 collimates the pulse laser beam PL1 having a wavelength of 515 nm approximately and emitted from the first solid-state laser apparatus 10A.

The second solid-state laser apparatus 20 emits the pulse laser beam PL2 having a wavelength of 1553 nm approximately. The polarization direction of the pulse laser beam PL2 is perpendicular to the sheet of FIG. 3. The pulse laser beam PL2 is incident on the dichroic mirror 39 through the beam expander lens 37. The beam expander lens 37 adjusts the beam diameter of the pulse laser beam PL2 having a wavelength of 1553 nm approximately and emitted from the second solid-state laser apparatus 20. A light condensing lens may be used in place of the beam expander lens 37.

The pulse laser beam PL1 having a wavelength of 515 nm approximately and emitted from the first solid-state laser apparatus 10A and the pulse laser beam PL2 having a wavelength of 1553 nm approximately and emitted from the second solid-state laser apparatus 20 are substantially simultaneously incident on the first CLBO crystal 61 through the dichroic mirror 39 with substantially identical optical path axes. The operation of the wavelength conversion system 60 will be described later.

The solid-state laser system 3A is an example of a “laser system” in the present disclosure. A laser system including the solid-state laser system 3A and the amplifier 5 is an example of a “laser system” in the present disclosure.

2.2.2 Operation of Wavelength Conversion System

The operation of the wavelength conversion system 60 illustrated in FIGS. 3 and 4 will be described below. The pulse laser beam PL1 having a wavelength of 515 nm approximately and emitted from the first solid-state laser apparatus 10A and the pulse laser beam PL2 having a wavelength of 1553 nm approximately and emitted from the second solid-state laser apparatus 20 are substantially simultaneously incident on the first CLBO crystal 61 through the first window 71 with substantially identical optical path axes.

The first CLBO crystal 61 is rotatable about a rotational axis parallel to the X axial direction by the first holder 81 and is adjusted so that the incident angle of the pulse laser beam PL1 having a wavelength of 515 nm approximately becomes a phase matching angle with which the phase matching condition of the first CLBO crystal 61 is satisfied.

As a result, a pulse laser beam having a wavelength of 257.5 nm approximately corresponding to the second harmonic of the pulse laser beam PL1 having a wavelength of 515 nm approximately is generated in the first CLBO crystal 61. Then, the pulse laser beam having a wavelength of 257.5 nm approximately and the pulse laser beam having a wavelength of 1553 nm approximately are emitted from the first CLBO crystal 61.

The polarization direction of the pulse laser beam having a wavelength of 257.5 nm approximately and emitted from the first CLBO crystal 61 is orthogonal to the polarization direction of the pulse laser beam having a wavelength of 1553 nm approximately. The term “orthogonal” or “perpendicular” in the present specification may include the concept of being substantially orthogonal or substantially perpendicular, which can be regarded being orthogonal in effect or perpendicular in effect in technological meanings. The polarization direction of the pulse laser beam having a wavelength of 257.5 nm approximately and emitted from the first CLBO crystal 61 is an example of a “second polarization direction” in the present disclosure. The pulse laser beam having a wavelength of 257.5 nm approximately and the pulse laser beam having a wavelength of 1553 nm approximately, both emitted from the first CLBO crystal 61 are substantially simultaneously incident on the second CLBO crystal 62 with substantially identical optical path axes.

The second CLBO crystal 62 is rotated about a rotational axis parallel to the Y axial direction by the second holder 82 to adjust the incident angles of the pulse laser beam having a wavelength of 257.5 nm approximately and the pulse laser beam having a wavelength of 1553 nm approximately so that the phase matching condition of the second CLBO crystal 62 is satisfied. As a result, a pulse laser beam having a wavelength of 220.9 nm approximately, which is sum frequency light of the pulse laser beam having a wavelength of 257.5 nm approximately and the pulse laser beam having a wavelength of 1553 nm approximately is generated through sum frequency mixing at the second CLBO crystal 62. The second CLBO crystal 62 emits the pulse laser beam having a wavelength of 220.9 nm approximately, the pulse laser beam having a wavelength of 257.5 nm approximately, and the pulse laser beam having a wavelength of 1553 nm approximately.

The polarization direction of the pulse laser beam having a wavelength of 220.9 nm approximately and emitted from the second CLBO crystal 62 is parallel to the polarization direction of the pulse laser beam having a wavelength of 1553 nm approximately. The pulse laser beam having a wavelength of 220.9 nm approximately, the pulse laser beam having a wavelength of 257.5 nm approximately, and the pulse laser beam having a wavelength of 1553 nm approximately are substantially simultaneously incident on the third CLBO crystal 63 with substantially identical optical path axes. The third CLBO crystal 63 is rotated about a rotational axis parallel to the X axial direction by the third holder 83 to adjust the incident angles of the pulse laser beam having a wavelength of 220.9 nm approximately and the pulse laser beam having a wavelength of 1553 nm approximately so that the phase matching condition of the third CLBO crystal 63 is satisfied. As a result, a pulse laser beam PL3 having a wavelength of 193.4 nm approximately, which is sum frequency light of the pulse laser beam having a wavelength of 220.9 nm approximately and the pulse laser beam having a wavelength of 1553 nm approximately is generated through sum frequency mixing at the third CLBO crystal 63.

The pulse laser beam PL3 generated by the third CLBO crystal 63 and having a wavelength of 193.4 nm approximately is emitted from the wavelength conversion system 60 through the second window 72.

The inside of the container 70 is purged with inert gas by introducing the inert gas into the container 70 through the gas introduction port 74 of the container 70 and discharging gas through the gas discharge port 76. The inert gas may be, for example, Ar gas. The flow rate of the inert gas may be, for example, 100 ml/min.

The wavelength conversion system 60 is configured as one compact unit in which three CLBO crystals are arranged in series in a space surrounded by the container 70. The term “unit” may be interchanged with “cell”.

The first CLBO crystal 61 is an example of a “first non-linear crystal” in the present disclosure. The first holder 81 is an example of a “first crystal holder” in the present disclosure. The second CLBO crystal 62 is an example of a “second non-linear crystal” in the present disclosure. The second holder 82 is an example of a “second crystal holder” in the present disclosure. The third CLBO crystal 63 is an example of a “third non-linear crystal” in the present disclosure. The third holder 83 is an example of a “third crystal holder” in the present disclosure. The rotational axis of the first holder 81 is an example of a “first rotational axis” in the present disclosure. The rotational axis of the second holder 82 is an example of a “second rotational axis” in the present disclosure. The rotational axis of the third holder 83 is an example of a “third rotational axis” in the present disclosure. The pulse laser beam PL1 having a wavelength of 515 nm approximately is an example of a “first pulse laser beam having a first wavelength” in the present disclosure. The pulse laser beam PL2 having a wavelength of 1553 nm approximately is an example of a “second pulse laser beam having a second wavelength” in the present disclosure. The pulse laser beam having a wavelength of 257.5 nm approximately and emitted from the first CLBO crystal 61 is an example of a “first harmonic light having a third wavelength” in the present disclosure. The pulse laser beam having a wavelength of 220.9 nm approximately and emitted from the second CLBO crystal 62 is an example of a “first sum frequency light having a fourth wavelength” in the present disclosure. The pulse laser beam having a wavelength of 193.4 nm approximately and emitted from the third CLBO crystal 63 is an example of each of a “second sum frequency light having a fifth wavelength” and a “third pulse laser beam” in the present disclosure.

2.3 Specific Example of Crystal Holder

2.3.1 Configuration

An example of crystal holders applied as the first holder 81, the second holder 82, and the third holder 83 will be described below. The first holder 81, the second holder 82, and the third holder 83 have substantially identical structures, and thus are collectively referred to as a holder 100 in the following description.

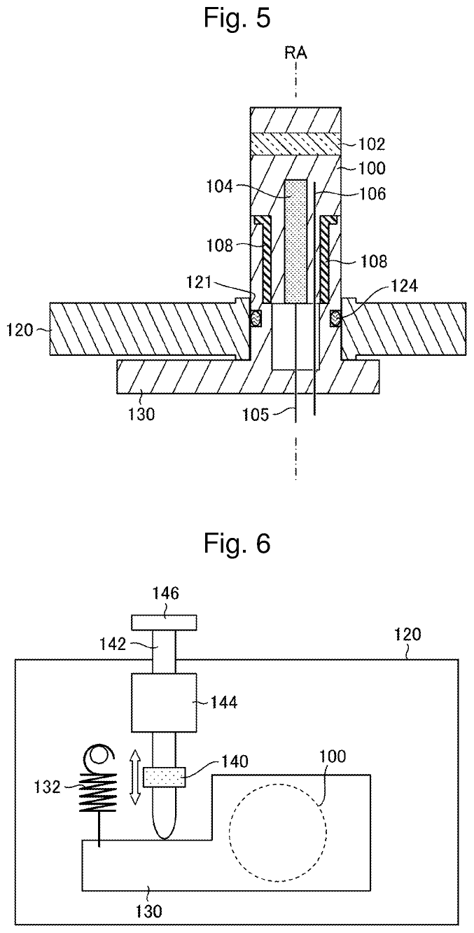

FIG. 5 is a cross-sectional view illustrating an exemplary configuration of the holder 100. FIG. 6 is a bottom view of the holder 100 illustrated in FIG. 5. A CLBO crystal 102 fixed to the holder 100 may have, for example, a rectangular parallelepiped shape with an edge area of 5×5 mm² and a length of 10 to 30 mm. The CLBO crystal 102 is fixed to the holder 100 having a cylindrical shape. The holder 100 includes a heater 104 and a thermocouple 106.

The heater 104 is inserted into the holder 100 and fixed. The heater 104 is connected to a non-illustrated heater power source through a heater wire 105. The heater power source is electrically connected to the solid-state laser control unit 56 through a non-illustrated wire. The thermocouple 106 is disposed inside the holder 100 and measures the temperature of a part at which the CLBO crystal 102 is fixed in the holder 100. The thermocouple 106 is an example of a “temperature sensor” in the present disclosure. The heater power source and the thermocouple 106 each are electrically connected to the solid-state laser control unit 56 through a non-illustrated wire.

The holder 100 is inserted into a hole 121 of a substrate 120 and rotatably supported about a rotational axis RA. A connecting portion of the holder 100 and the substrate 120 is sealed by an O ring 124. The substrate 120 to which the holder 100 is attached may be part of a wall surface of the container 70.

The holder 100 includes, as a mechanism for rotating the holder 100, a rotation bar 130, a spring 132, a piezoelectric element 140, a bar 142, a bar fixing member 144, and a handle 146.

A base end part of the holder 100 in the direction of the rotational axis RA is fixed to the rotation bar 130. The rotation bar 130 is disposed orthogonal to the rotational axis RA of the holder 100. The spring 132 has one end part connected to the rotation bar 130 and the other end part connected to the substrate 120.

The piezoelectric element 140 and the bar 142 are disposed to press the rotation bar 130. The handle 146 is provided at an end part of the bar 142.

The bar fixing member 144 is fixed to the substrate 120. The bar 142 is supported by the bar fixing member 144.

In addition, a heat insulating member 108 is provided to the holder 100 to reduce temperature increase at the 0 ring 124, the rotation bar 130, the substrate 120, and any other component due to heat of the heater 104. The heat insulating member 108 is disposed to surround the heater 104 inside the holder 100.

2.3.2 Operation

The operation of the holder 100 illustrated in FIGS. 5 and 6 will be described below. Electric power is supplied from the heater power source to the heater 104, and the temperature of a part including the CLBO crystal 102 in the holder 100 is heated to, for example, 150° C. while the temperature is monitored by the thermocouple 106. Dehydration processing of the CLBO crystal 102 is performed through the heating.

The piezoelectric element 140 is driven to expand and contract to adjust the incident angle of a laser beam on the CLBO crystal 102. The holder 100 can be rotated about the rotational axis RA through the rotation bar 130 through the expansion and contraction of the piezoelectric element 140. The rotation angle of the holder 100 can be adjusted by adjusting the amount of expansion and contraction of the piezoelectric element 140. In this manner, the rotation angle can be adjusted at high resolution by using the piezoelectric element 140.

When the holder 100 is used as the first holder 81, the CLBO crystal 102 is the first CLBO crystal 61 and the rotational axis RA is a rotational axis parallel to the X axial direction. When the holder 100 is used as the second holder 82, the CLBO crystal 102 is the second CLBO crystal 62 and the rotational axis RA is a rotational axis parallel to the Y axial direction. When the holder 100 is used as the third holder 83, the CLBO crystal 102 is the third CLBO crystal 63 and the rotational axis RA is a rotational axis parallel to the X axial direction.

2.4 Effects

In the wavelength conversion system 60 according to Embodiment 1, the polarization directions of the pulse laser beam having a wavelength of 257.5 nm approximately and the pulse laser beam having a wavelength of 1553 nm approximately, both emitted from the first CLBO crystal 61 are orthogonal to each other. The second CLBO crystal 62 is a wavelength conversion crystal having a phase matching condition of type 2 for pulse laser beams having polarization directions orthogonal to each other. Thus, it is unnecessary to provide, between the first CLBO crystal 61 and the second CLBO crystal 62, a configuration in which a pulse laser beam is bifurcated into two pulse laser beams by using an optical element such as a dichroic mirror, the polarization direction of one of the pulse laser beams is rotated by 90° through a half-wavelength plate, and then the optical paths of the two pulse laser beams are merged through another optical element.

The polarization directions of the pulse laser beam having a wavelength of 220.9 nm approximately and the pulse laser beam having a wavelength of 1553 nm approximately, both emitted from the second CLBO crystal 62 are parallel to each other. The third CLBO crystal 63 is a wavelength conversion crystal having a phase matching condition of type 1 for pulse laser beams having polarization directions parallel to each other. Thus, it is unnecessary to provide, between the second CLBO crystal 62 and the third CLBO crystal 63, for example, optical elements for bifurcating a pulse laser beam and merging pulse laser beams and a half-wavelength plate for rotating the polarization direction of one of the pulse laser beams by 90°.

As described above, in the wavelength conversion system 60 according to Embodiment 1, the optical path length from the first CLBO crystal 61 to the third CLBO crystal 63 can be reduced, and the wavelength conversion system 60 including a plurality of CLBO crystals can be configured as one compact unit.

Further, in the wavelength conversion system 60 according to Embodiment 1, the first CLBO crystal 61, the second CLBO crystal 62, and the third CLBO crystal 63 are collectively housed in the space surrounded by the container 70, and thus dehydration processing and purge for preventing water adhesion can be efficiently performed on the CLBO crystals through gas introduction to the internal space of the container 70 and gas discharge from the internal space. In addition, with the wavelength conversion system 60 according to Embodiment 1, maintainability in CLBO crystal replacement work and the like improves.

Furthermore, in the wavelength conversion system 60, the optical path length between the first CLBO crystal 61 and the second CLBO crystal 62 and the optical path length between the second CLBO crystal 62 and the third CLBO crystal 63 are short, which leads to small pulse laser beam misalignment through each optical path between crystals. Thus, it is easy to adjust alignment with which a phase matching condition is satisfied, and it is possible to reduce a time taken for adjusting alignment.

Moreover, no optical element needs to be disposed on an optical path from the first CLBO crystal 61 to the third CLBO crystal 63, which suppresses a pulse laser beam loss. In addition, no optical element that would be damaged by a pulse laser beam is disposed on the optical path from the first CLBO crystal 61 to the third CLBO crystal 63, which extends the lifetime of the wavelength conversion system 60.

### 3. Embodiment 2

3.1 Configuration

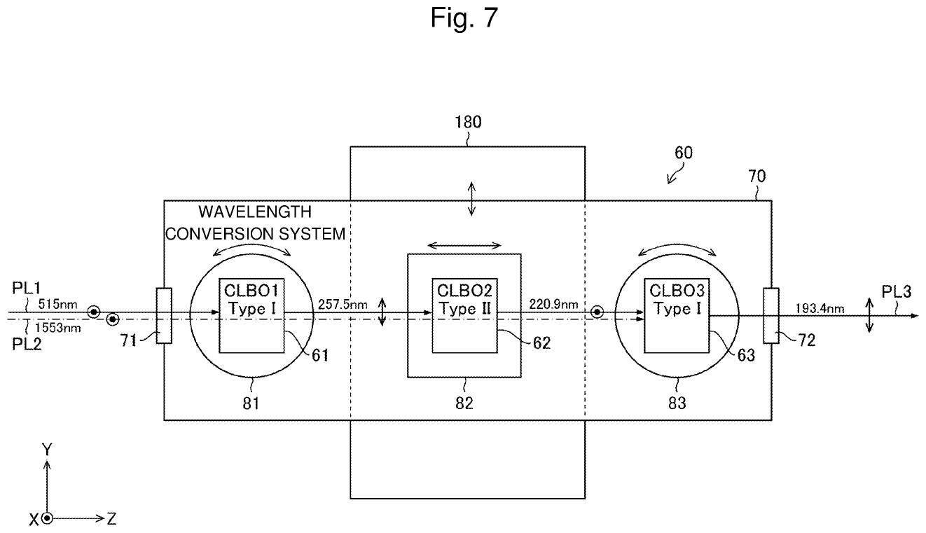

FIG. 7 schematically illustrates an exemplary configuration of the wavelength conversion system 60 according to Embodiment 2. In FIG. 7, a component same as in the configuration illustrated in FIG. 4 is denoted by the same reference sign, and description thereof is omitted as appropriate. FIG. 7 omits illustrations of the gas supply path including the valve 75 and the gas discharge path including the valve 77, which are described with reference to FIG. 4.

The wavelength conversion system 60 according to Embodiment 2 illustrated in FIG. 7 is disposed on a movement stage 180 configured to move in the Y axial direction and the X axial direction. Specifically, the container 70 of the wavelength conversion system 60 is fixed to the movement stage 180 that is movable in the Y axial direction and the X axial direction. The movement stage 180 is electrically connected to the solid-state laser control unit 56 through a non-illustrated signal line. The wavelength conversion system 60 may include the movement stage 180 and may further include the solid-state laser control unit 56 that controls the movement stage 180.

3.2 Operation

In the configuration of Embodiment 2 illustrated in FIG. 7, the solid-state laser control unit 56 can move the container 70 of the wavelength conversion system 60 in at least one of the X axial direction and the Y axial direction by controlling the movement stage 180. The positions of incident points at which a pulse laser beam is incident on the first CLBO crystal 61, the second CLBO crystal 62, and the third CLBO crystal 63 in the container 70 are changed by moving the movement stage 180.

The operation of movement through the movement stage 180 may be periodically performed or may be performed based on determination on laser characteristics such as the number of shot pulse laser beams and the measured value of pulse energy. The movement stage 180 is an example of a “movement apparatus” in the present disclosure.

3.3 Effects

According to Embodiment 2, in addition to effects obtained with Embodiment 1, it is possible to change a position at which a CLBO crystal is used, and thus it is possible to increase a time in which one CLBO crystal can be used or the number of pulses of a pulse laser beam that can be subjected to wavelength conversion.

### 4. Embodiment 3

4.1 Configuration

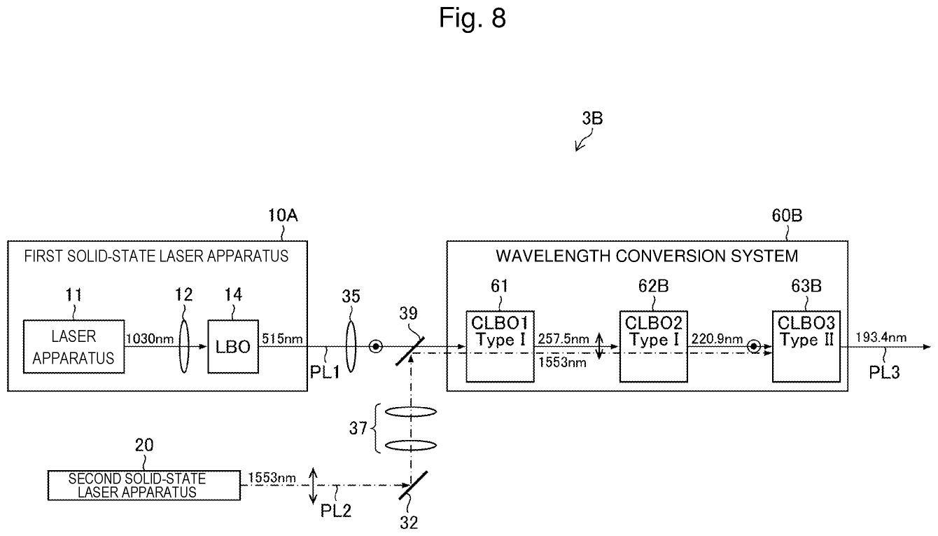

FIG. 8 schematically illustrates an exemplary configuration of a solid-state laser system 3B including a wavelength conversion system 60B according to Embodiment 3. In Embodiment 3, the solid-state laser system 3B illustrated in FIG. 8 is applied in place of the solid-state laser system 3 described with reference to FIG. 1. In FIG. 8, a part same as a component of the solid-state laser system 3A according to Embodiment 1 illustrated in FIG. 3 is denoted by the same reference sign, and description thereof is omitted as appropriate.

The wavelength conversion system 60B includes the first CLBO crystal 61, a second CLBO crystal 62B, and a third CLBO crystal 63B. The first CLBO crystal 61 and the second CLBO crystal 62B each are a wavelength conversion crystal having a phase matching condition of type 1. The third CLBO crystal 63B is a wavelength conversion crystal having a phase matching condition of type 2. The other configuration is same as the configuration described with reference to FIGS. 4 to 6.

Specifically, the first CLBO crystal 61 is fixed to the first holder 81, the second CLBO crystal 62B is fixed to the second holder 82, and the third CLBO crystal 63B is fixed to the third holder 83. The first holder 81, the second holder 82, and the third holder 83 are housed in the container 70 having the first window 71 and the second window 72. The container 70 is provided with the gas introduction port 74 and the gas discharge port 76.

4.2 Operation

The operation of the solid-state laser system 3B illustrated in FIG. 8 will be described below with a focus on any difference from that of the solid-state laser system 3A illustrated in FIG. 3. The polarization direction of the pulse laser beam PL2 emitted from the second solid-state laser apparatus 20 illustrated in FIG. 8 is a longitudinal direction parallel to the sheet of FIG. 8.

The polarization directions of the pulse laser beam PL1 having a wavelength of 515 nm approximately and the pulse laser beam PL2 having a wavelength of 1553 nm approximately, both incident on the first CLBO crystal 61 are orthogonal to each other. The incident angle on the first CLBO crystal 61 is adjusted so that the phase matching condition thereof is satisfied by the pulse laser beam PL1 having a wavelength of 515 nm approximately. As a result, a pulse laser beam having a wavelength of 257.5 nm approximately corresponding to the second harmonic of the pulse laser beam PL1 having a wavelength of 515 nm approximately is generated.

The polarization directions of the pulse laser beam having a wavelength of 257.5 nm approximately and the pulse laser beam having a wavelength of 1553 nm approximately, both emitted from the first CLBO crystal 61 are parallel to each other. The pulse laser beam having a wavelength of 257.5 nm approximately and the pulse laser beam having a wavelength of 1553 nm approximately are substantially simultaneously incident on the second CLBO crystal 62B with substantially identical optical path axes.

The incident angle on the second CLBO crystal 62B is adjusted so that the phase matching condition thereof is satisfied by the pulse laser beam having a wavelength of 257.5 nm approximately and the pulse laser beam having a wavelength of 1553 nm approximately. As a result, a pulse laser beam having a wavelength of 220.9 nm approximately, which is the sum frequency of the pulse laser beam having a wavelength of 257.5 nm approximately and the pulse laser beam having a wavelength of 1553 nm approximately is generated at the second CLBO crystal 62B. The second CLBO crystal 62B emits the pulse laser beam having a wavelength of 220.9 nm approximately, the pulse laser beam having a wavelength of 257.5 nm approximately, and the pulse laser beam having a wavelength of 1553 nm approximately.

The polarization directions of the pulse laser beam having a wavelength of 220.9 nm approximately and the pulse laser beam having a wavelength of 1553 nm approximately, both emitted from the second CLBO crystal 62B are orthogonal to each other. The pulse laser beam having a wavelength of 220.9 nm approximately, the pulse laser beam having a wavelength of 257.5 nm approximately, and the pulse laser beam having a wavelength of 1553 nm approximately are substantially simultaneously incident on the third CLBO crystal 63B with substantially identical optical path axes. The incident angle on the third CLBO crystal 63B is adjusted so that the phase matching condition thereof is satisfied by the pulse laser beam having a wavelength of 220.9 nm approximately and the pulse laser beam having a wavelength of 1553 nm approximately. As a result, a pulse laser beam PL3 having a wavelength of 193.4 nm approximately, which is the sum frequency of the pulse laser beam having a wavelength of 220.9 nm approximately and the pulse laser beam having a wavelength of 1553 nm approximately is generated.

The pulse laser beam having a wavelength of 220.9 nm approximately and emitted from the second CLBO crystal 62B is an example of a “first sum frequency light having a fourth wavelength” in the present disclosure. The pulse laser beam having a wavelength of 193.4 nm approximately and emitted from the third CLBO crystal 63B is an example of a “second sum frequency light having a fifth wavelength” in the present disclosure.

4.3 Effects

In the wavelength conversion system 60B according to Embodiment 3, the polarization directions of the pulse laser beam having a wavelength of 257.5 nm approximately and the pulse laser beam having a wavelength of 1553 nm approximately, both emitted from the first CLBO crystal 61 are parallel to each other. The second CLBO crystal 62B is a wavelength conversion crystal having a phase matching condition of type 1 for pulse laser beams having polarization directions parallel to each other. Thus, in Embodiment 3, it is unnecessary to provide, between the first CLBO crystal 61 and the second CLBO crystal 62, a configuration in which a pulse laser beam is bifurcated into two pulse laser beams by using an optical element such as a dichroic mirror, the polarization direction of one of the pulse laser beams is rotated by 90° through a half-wavelength plate, and then the optical paths of the two pulse laser beams are merged through another optical element.

The polarization directions of the pulse laser beam having a wavelength of 220.9 nm approximately and the pulse laser beam having a wavelength of 1553 nm approximately, both emitted from the second CLBO crystal 62B are orthogonal to each other. The third CLBO crystal 63B is a wavelength conversion crystal having a phase matching condition of type 2 for pulse laser beams having polarization directions orthogonal to each other. Thus, it is unnecessary to provide, between the second CLBO crystal 62 and the third CLBO crystal 63, for example, optical elements for bifurcating a pulse laser beam and merging pulse laser beams and a half-wavelength plate for rotating the polarization direction of one of the pulse laser beams by 90°.

As described above, in the wavelength conversion system 60B according to Embodiment 3, the optical path length from the first CLBO crystal 61 to the third CLBO crystal 63B can be reduced, and the wavelength conversion system 60B including a plurality of CLBO crystals can be configured as one compact unit.

Further, in the wavelength conversion system 60B according to Embodiment 3, the first CLBO crystal 61, the second CLBO crystal 62B, and the third CLBO crystal 63B are collectively housed in the space surrounded by the container 70, and thus dehydration processing and purge for preventing water adhesion can be efficiently performed on the CLBO crystals. In addition, with the wavelength conversion system 60B according to Embodiment 3, maintainability in CLBO crystal replacement work and the like improves.

Furthermore, in the wavelength conversion system 60B, the optical path length between the first CLBO crystal 61 and the second CLBO crystal 62B and the optical path length between the second CLBO crystal 62B and the third CLBO crystal 63B are short, which leads to small pulse laser beam misalignment through each optical path between crystals. Thus, it is easy to adjust alignment with which a phase matching condition is satisfied, and it is possible to reduce a time taken for adjusting alignment.

Moreover, no optical element needs to be disposed on an optical path from the first CLBO crystal 61 to the third CLBO crystal 63B, which suppresses a pulse laser beam loss. In addition, no optical element that would be damaged by a pulse laser beam is disposed on the optical path from the first CLBO crystal 61 to the third CLBO crystal 63B, which extends the lifetime of the wavelength conversion system 60B.

4.4 Modification

The wavelength conversion system 60B according to Embodiment 3 may employ a configuration including the movement stage 180 described in Embodiment 2.

### 5. Example of Wavelength Adjustable Range

Table 1 lists exemplary wavelength adjustable ranges in each of Embodiments 1 to 3. When the wavelength of the pulse laser beam PL1 emitted from the first solid-state laser apparatus 10A is fixed to 515 nm approximately and the wavelength of the pulse laser beam PL2 emitted from the second solid-state laser apparatus 20 is changed in the range of 1549 nm to 1557 nm inclusive, the wavelength of the second harmonic light emitted from the first CLBO crystal 61 is 257.5 nm approximately (fixed) and the wavelength of the first sum frequency light emitted from the second CLBO crystal 62 or 62B changes in the range of 220.80 nm to 220.96 nm inclusive. In this case, the wavelength of the second sum frequency light emitted from the third CLBO crystal 63 or 63B changes in the range of 193.25 nm to 193.50 nm inclusive.

TABLE 1

| | Wavelength adjustable range (nm) |
|---|---|
| PL1 | 515 (fixed) |
| PL2 | 1549 to 1557 |
| Second harmonic light of PL1 | 257.5 |
| First sum frequency light | 220.80 to 220.96 |
| Second sum frequency light (PL3) | 193.25 to 193.50 |

The following relation is satisfied when the wavelength of the pulse laser beam PL1 is referred to as a first wavelength, the wavelength of the pulse laser beam PL2 is referred to as a second wavelength, the wavelength of the second harmonic light emitted from the first CLBO crystal 61 is referred to as a third wavelength, the wavelength of the first sum frequency light emitted from the second CLBO crystal 62 or 62B is referred to as a fourth wavelength, and the wavelength of the second sum frequency light emitted from the third CLBO crystal 63 or 63B is referred to as a fifth wavelength.

Second wavelength >first wavelength >third wavelength >fourth wavelength >fifth wavelength

### 6. Modifications

(1) Embodiments 1 and 2 describe an example in which three CLBO crystals having phase matching conditions of the corresponding types are arranged in the order of type 1, type 2, and type 1 from the laser-beam incident side in the wavelength conversion system 60, and Embodiment 3 describes an example in which the CLBO crystals are arranged in the order of type 1, type 1, and type 2, but the order of arrangement of the types of phase matching condition is not limited to these examples. It suffices that non-linear crystals having phase matching conditions of type 1 and non-linear crystals having phase matching conditions of type 2 are disposed in series on an optical path in mixture. When the wavelength conversion described above in the embodiments is performed, a non-linear crystal disposed first preferably has a phase matching condition of type 1.

(2) Embodiments 1 to 3 describe an example of a wavelength conversion system in which three CLBO crystals are disposed in series on an optical path, but the wavelength conversion system may include four or more non-linear crystals. Specifically, any additional non-linear crystal may be disposed on the same optical path in addition to three CLBO crystals described in the embodiments. For example, the wavelength conversion system may have a configuration in which at least one additional non-linear crystal is disposed on an optical path between the first window 71 and the first CLBO crystal 61 or on an optical path between the third CLBO crystal 63 and the second window 72 illustrated in FIG. 4, or on each of the optical paths. The “additional non-linear crystal” may be a CLBO crystal or may be a crystal of a kind other than CLBO.

(3) Although each above-described embodiment describes an example of a wavelength conversion system including CLBO crystals, a non-linear crystal is not limited to a CLBO crystal but may be a crystal of another kind. For example, the non-linear crystal may be BBO (β-BaB₂O₄) crystal or an LBO crystal. At least one of a plurality of non-linear crystals included in the wavelength conversion system may be a BBO crystal or an LBO crystal.

7. Electronic Device Manufacturing Method

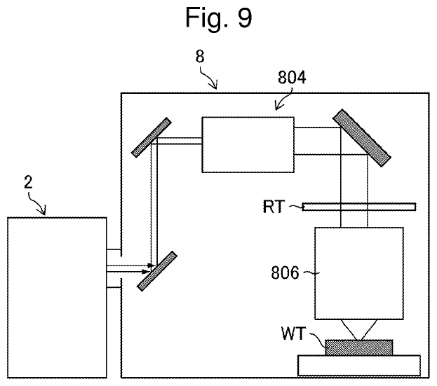

FIG. 9 is a diagram schematically illustrating an exemplary configuration of the exposure apparatus 8. The exposure apparatus 8 includes an illumination optical system 804 and a projection optical system 806. The illumination optical system 804 illuminates a reticle pattern on a reticle stage RT with a laser beam incident from the laser apparatus 2. The projection optical system 806 images, through reduced projection, the laser beam having transmitted through a reticle onto a non-illustrated workpiece disposed on a workpiece table WT. The workpiece is a photosensitive substrate such as a semiconductor wafer on which photoresist is applied.

The exposure apparatus 8 translates the reticle stage RT and the workpiece table WT in synchronization to expose the workpiece to the laser beam reflecting the reticle pattern. A semiconductor device can be manufactured through a plurality of processes after the reticle pattern is transferred onto the semiconductor wafer through the above-described exposure process. The semiconductor device is an example of an “electronic device” in the present disclosure.

The laser apparatus 2 in FIG. 9 may include the solid-state laser system 3A or 3B described in the embodiments.

### 8. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A wavelength conversion system comprising:
a first crystal holder holding a first non-linear crystal;
a second crystal holder holding a second non-linear crystal;
a third crystal holder holding a third non-linear crystal; and
a container housing the first crystal holder, the second crystal holder, and the third crystal holder,
the container having an entrance window and an emission window,
the first non-linear crystal, the second non-linear crystal, and the third non-linear crystal being disposed in this order on an optical path of a laser beam traveling from the entrance window to the emission window,
the first crystal holder, the second crystal holder, and the third crystal holder each being rotatable,
a first rotational axis that is a rotational axis of the first crystal holder being orthogonal to a second rotational axis that is a rotational axis of the second crystal holder, the first rotational axis being parallel to a third rotational axis that is a rotational axis of the third crystal holder.

2. The wavelength conversion system according to claim 1, wherein
when having received a first pulse laser beam having a first wavelength and a second pulse laser beam having a second wavelength, the first non-linear crystal emits first harmonic light and the second pulse laser beam, the first harmonic light having a third wavelength corresponding to a second harmonic of the first wavelength,
when having received the first harmonic light and the second pulse laser beam emitted from the first non-linear crystal, the second non-linear crystal emits first sum frequency light and the second pulse laser beam, the first sum frequency light having a fourth wavelength generated through sum frequency mixing of the third wavelength and the second wavelength, and
when having received the first sum frequency light and the second pulse laser beam emitted from the second non-linear crystal, the third non-linear crystal emits a third pulse laser beam that is second sum frequency light with a fifth wavelength generated through sum frequency mixing of the fourth wavelength and the second wavelength.

3. The wavelength conversion system according to claim 2, wherein
polarization directions of the first pulse laser beam and the second pulse laser beam received by the first non-linear crystal are parallel to each other,
a polarization direction of the first harmonic light emitted from the first non-linear crystal is a second polarization direction orthogonal to a first polarization direction of the first pulse laser beam,
the polarization directions of the first harmonic light and the second pulse laser beam received by the second non-linear crystal are orthogonal to each other,
a polarization direction of the first sum frequency light emitted from the second non-linear crystal is the first polarization direction,
the polarization directions of the first sum frequency light and the second pulse laser beam received by the third non-linear crystal are parallel to each other, and
a polarization direction of the second sum frequency light emitted from the third non-linear crystal is the second polarization direction.

4. The wavelength conversion system according to claim 2, wherein
the first non-linear crystal has a phase matching condition of type 1,
the second non-linear crystal has a phase matching condition of type 2, and
the third non-linear crystal has a phase matching condition of type 1.

5. The wavelength conversion system according to claim 2, wherein
polarization directions of the first pulse laser beam and the second pulse laser beam received by the first non-linear crystal are orthogonal to each other,
a polarization direction of the first harmonic light emitted from the first non-linear crystal is a second polarization direction orthogonal to a first polarization direction of the first pulse laser beam,
the polarization directions of the first harmonic light and the second pulse laser beam received by the second non-linear crystal are parallel to each other,
a polarization direction of the first sum frequency light emitted from the second non-linear crystal is the first polarization direction,
the polarization directions of the first sum frequency light and the second pulse laser beam received by the third non-linear crystal are orthogonal to each other, and
a polarization direction of the second sum frequency light emitted from the third non-linear crystal is the second polarization direction.

6. The wavelength conversion system according to claim 2, wherein
the first non-linear crystal has a phase matching condition of type 1,
the second non-linear crystal has a phase matching condition of type 1, and
the third non-linear crystal has a phase matching condition of type 2.

7. The wavelength conversion system according to claim 2, wherein
the wavelength conversion system satisfies a following relation:
the second wavelength >the first wavelength >the third wavelength >the fourth wavelength >the fifth wavelength.

8. The wavelength conversion system according to claim 2, wherein
the first wavelength is 515 nm,
the second wavelength is 1549 nm to 1557 nm inclusive,
the third wavelength is 257.5 nm,
the fourth wavelength is 220.80 nm to 220.96 nm inclusive, and
the fifth wavelength is 193.25 nm to 193.50 nm inclusive.

9. The wavelength conversion system according to claim 1, wherein
the first non-linear crystal, the second non-linear crystal, and the third non-linear crystal each are a CLBO crystal.

10. The wavelength conversion system according to claim 1, wherein
at least one of the first non-linear crystal, the second non-linear crystal, and the third non-linear crystal is a BBO crystal.

11. The wavelength conversion system according to claim 1, wherein
at least one of the first non-linear crystal, the second non-linear crystal, and the third non-linear crystal is an LBO crystal.

12. The wavelength conversion system according to claim 1, wherein
the container has a gas introduction port through which inert gas is introduced into the container, and a gas discharge port through which the inert gas is discharged from the container.

13. The wavelength conversion system according to claim 1, wherein
when a Z axial direction is defined to be a direction of an optical path axis in the container, an X axial direction is defined to be a first direction orthogonal to the optical path axis, and a Y axial direction is defined to be a second direction orthogonal to the optical path axis and the first direction,
the first rotational axis and the third rotational axis are parallel to the X axial direction, and
the second rotational axis is parallel to the Y axial direction.

14. The wavelength conversion system according to claim 1, further comprising
a movement apparatus configured to move the container in a first direction and a second direction, the first direction being orthogonal to an optical path axis in the container, the second direction being orthogonal to the optical path axis and the first direction.

15. The wavelength conversion system according to claim 1, wherein
the first crystal holder, the second crystal holder, and the third crystal holder each include a rotation mechanism configured to adjust a rotation angle by using a piezoelectric element.

16. The wavelength conversion system according to claim 1, wherein
a heater and a temperature sensor are disposed inside each of the first crystal holder, the second crystal holder, and the third crystal holder.

17. A laser system comprising:
a first solid-state laser apparatus configured to emit a first pulse laser beam;
a second solid-state laser apparatus configured to emit a second pulse laser beam; and
a wavelength conversion system configured to emit a third pulse laser beam having a wavelength different from wavelengths of the first pulse laser beam and the second pulse laser beam when having received the first pulse laser beam and the second pulse laser beam,
the wavelength conversion system including:
a first crystal holder holding a first non-linear crystal;
a second crystal holder holding a second non-linear crystal;
a third crystal holder holding a third non-linear crystal; and
a container housing the first crystal holder, the second crystal holder, and the third crystal holder,
the container having an entrance window and an emission window,
the first non-linear crystal, the second non-linear crystal, and the third non-linear crystal being disposed in this order on an optical path of a laser beam traveling from the entrance window to the emission window,
the first crystal holder, the second crystal holder, and the third crystal holder each being rotatable,
a first rotational axis that is a rotational axis of the first crystal holder being orthogonal to a second rotational axis that is a rotational axis of the second crystal holder, the first rotational axis being parallel to a third rotational axis that is a rotational axis of the third crystal holder.

18. The laser system according to claim 17, further comprising
an amplifier configured to amplify the third pulse laser beam emitted from the wavelength conversion system.

19. An electronic device manufacturing method comprising:
generating a laser beam with a laser system including a wavelength conversion system including
a first crystal holder holding a first non-linear crystal,
a second crystal holder holding a second non-linear crystal,
a third crystal holder holding a third non-linear crystal, and
a container housing the first crystal holder, the second crystal holder, and the third crystal holder,
the container having an entrance window and an emission window,
the first non-linear crystal, the second non-linear crystal, and the third non-linear crystal being disposed in this order on an optical path of a laser beam traveling from the entrance window to the emission window,
the first crystal holder, the second crystal holder, and the third crystal holder each being rotatable,
a first rotational axis that is a rotational axis of the first crystal holder being orthogonal to a second rotational axis that is a rotational axis of the second crystal holder, the first rotational axis being parallel to a third rotational axis that is a rotational axis of the third crystal holder;
emitting the laser beam to an exposure apparatus; and
exposing a photosensitive substrate to the laser beam within the exposure apparatus to manufacture an electronic device.
